(19) United States
(12) Patent Application Publication
(10) Pub. No.: US 2010/0079211 A1
(43) Pub. Date: Apr. 1, 2010

(54) MATCHING CIRCUIT, AND RADIO-FREQUENCY POWER AMPLIFIER AND MOBILE PHONE INCLUDING THE SAME

(75) Inventors: Shingo MATSUDA, Kyoto (JP); Kazuki TATEOKA, Kyoto (JP); Masahiko INAMORI, Osaka (JP); Hirokazu MAKIHARA, Osaka (JP); Junji KAIDO, Osaka (JP)

Correspondence Address: GREENBLUM & BERNSTEIN, P.L.C., 1950 ROLAND CLARKE PLACE, RESTON, VA, 20191, US

(73) Assignee: Panasonic Corporation, Osaka (JP)

(21) Appl. No.: 12/564,126

(22) Filed: Sep. 22, 2009

(30) Foreign Application Priority Data
Sep. 30, 2008 (JP) 2008-255801

(51) Int. Cl. H03F 3/04; H03H 7/38

(52) U.S. Cl. 330/306; 333/33

(57) ABSTRACT

Provided is a matching circuit, radio-frequency power amplifier, and mobile phone whereby the second harmonic can be suppressed and the loss of fundamental due to the self resonant frequency of components can be reduced. The output matching circuit includes: a transmission line through which a radio-frequency signal is transmitted; and resonators each of which includes a capacitor. The resonators respectively have (i) first terminals connected to substantially a same connecting point on the transmission line and (ii) second terminals that are grounded.

### BACKGROUND OF THE INVENTION

(1) Field of the Invention

The present invention relates to a matching circuit, a radio-frequency power amplifier (hereinafter referred to as RF power amplifier), and a mobile phone, and in particular to a matching circuit that matches an input impedance and an output impedance, an RF power amplifier and a mobile phone each including such a matching circuit.

(2) Description of the Related Art

In recent years, there is an increasing demand for mobile communication apparatuses, such as mobile phones to support (i) multiband communication using frequency bands to secure communication capacity and (ii) multimode communication with communication systems through international roaming services. Currently, dominant communication systems are divided into two categories, that is, (i) the second generation system using Global System for Mobile Communication (GSM) standard and (ii) the third generation system using Code Division Multiple Access (CDMA) system. The frequency bands used for transmission in these communication systems includes Band I ranging from 1920 MHz to 1980 MHz, Band II ranging from 1850 MHz to 1910 MHz, Band III ranging from 1710 MHz to 1785 MHz, Band IV ranging from 1710 MHz to 1755 MHz, Band V ranging from 824 MHz to 849 MHz, Band VI ranging from 830 MHz to 840 MHz, Band VIII ranging from 880 MHz to 915 MHz, and Band IX ranging from 1749.9 MHz to 1784.9 MHz. The combinations of the communication systems and these frequency bands differ, depending on a region where the mobile phones are used. In order to support these communication systems, each wireless communication unit included therein needs a plurality of RF power amplifiers, so that there is an increasing demand for miniaturization of the RF power amplifiers.

However, the RF power amplifiers feature the highest power consumption, and input and output of higher electric power, compared with other components included in each wireless communication unit. Thus, devices, such as power amplification transistors included in these RF power amplifiers need to have size corresponding to such high output power, which makes it difficult to simply miniaturize the RF power amplifiers.

Furthermore, resistance values in circuits that are used in wireless communication and are included in mobile phones are set to 50 ohm as the general standard. Furthermore, each of the power amplification transistors included in the RF power amplifiers includes an input matching circuit and an output matching circuit for matching impedances of components in the RF power amplifiers to those of components connected upstream and downstream of the RF power amplifiers. These matching circuits include inductors, capacitors, and microstriplines, and each of the components has limitation in the miniaturization due to each physical length and size.

Thus, much attention is given to the RF power amplifiers that enable the multiband and multimode communication in a single amplification path.

On the other hand, impedances of the matching circuits depend on each frequency because inductors, capacitors, and microstriplines are used in the matching circuits included in the RF power amplifiers, and thus an output power characteristic and an efficiency characteristic depend on each frequency. Accordingly, a multiband matching circuit is suggested which includes switch elements and sub-matching blocks for matching impedances and which converts the impedances (see Japanese Unexamined Patent Application Publication No. 2006-325153 referred to as Patent Reference 1 hereinafter).

FIG. 34 illustrates a structure of a matching circuit that supports multiband communication and that is described in Patent Reference 1. The multiband communication in the matching circuit becomes possible by matching an impedance of the first matching block to an impedance of the second matching block in a certain frequency band, whereas by turning on the switch elements and using the sub-matching blocks in another frequency band. Thereby, the matching circuit described in Patent Reference 1 can amplify a signal larger than second harmonic having a bandwidth twice a bandwidth of the fundamental.

Furthermore, as another structure of the matching circuits, the output matching circuits included in the power amplification transistors of the RF power amplifiers preferably include two-stage lowpass filters as main matching circuit units. Such a two-stage lowpass filter includes an inductor connected in series with a signal line and a capacitor that is grounded, or an inductor connected in series with a microstripline and a capacitor that is grounded (for example, see Japanese Unexamined Patent Application Publication No. 2003-298364 referred to as Patent Reference 2 hereinafter). FIG. 35 illustrates an output matching circuit described in Patent Reference 2, as an example of such a circuit structure.

### SUMMARY OF THE INVENTION

However, the matching circuit described in Patent Reference 1 needs switch elements additionally including semiconductor devices and other elements, terminals, connection paths, and a control circuit for controlling the switch elements. Thus, the matching circuit has the limitation in the miniaturization and cost reduction.

Furthermore, the lower limit of frequency bands for use in the mobile phones is 824 MHz, and the upper limit is 1980 MHz that is more than double the lower limit. Thus, a circuit structure described in Patent Reference 2 has a problem when one matching circuit amplifies signals in all of these frequency bands. For example, since the second harmonic in Band VIII is within the frequency bands of Band IV and Band IX, the second harmonic cannot be suppressed and an unnecessary emission of a signal in Band VIII cannot be suppressed. In other words, although the structure in FIG. 35 can suppress the second harmonic in a lower frequency band, such structure cannot satisfy the electric power needed in all frequency bands.

Here, assume that 824 MHz to 915 MHz covering Band V, Band VI, and Band VIII is set to a frequency band X, and 710 MHz to 1980 MHz covering Band I, Band II, Band III, Band IV, and Band IX is set to another frequency band Y. Each of the set frequency bands X and Y never includes any second harmonic. Furthermore, the frequency band X includes the 3 bands of Band V, Band VI, and Band VIII in a lower frequency band, and the frequency band Y includes the 5 bands of Band I, Band II, Band III, Band IV, and Band IX in a higher frequency band. Furthermore, the miniaturization of communication systems can be improved, in a multiband mode operation, with a structure including transmission paths corresponding to the frequency bands X and Y respectively in the lower frequency band and in the higher frequency band. However, broadband matching for multiband communication under the structure of FIG. 35 is difficult due to the following reasons.

In this structure, components used as constituent elements of an actual circuit cannot suppress the second harmonic in the higher frequency band, due to self resonant frequencies of the components, and further increases loss of a signal in the higher frequency band having the fundamental.

Thus, the present invention has an object of providing a matching circuit, RF power amplifier, and mobile phone whereby the second harmonic can be suppressed and the loss of the fundamental due to the self resonance of the components can be reduced.

In order to achieve the object, the matching circuit according to an aspect of the present invention includes: a transmission line through which a radio-frequency signal is transmitted; and resonators each of which includes a capacitor, the resonators respectively having (i) first terminals connected to substantially a same connecting point on the transmission line and (ii) second terminals that are grounded.

Thereby, a capacitance value for use in each resonator can be made equal to or half thereof. Furthermore, capacitance values are combined in an equivalent circuit obtained by synthesizing resonators, such that capacitance values necessary for matching impedances in a wider frequency band can satisfy a requirement of the matching circuit. Furthermore, a self resonant frequency of a single capacitor can be changed to a frequency equal to or twice a frequency the fundamental, and a radio-frequency signal can be suppressed at a desired frequency in a frequency band including the second harmonic by adjusting component values of the resonators.

Furthermore, each of the resonators may have a resonant frequency within a bandwidth twice a bandwidth of the radio-frequency signal transmitted through the matching circuit.

Thereby, the second harmonic can be further suppressed. Furthermore, one of the resonators may have a resonant frequency different from at least one of the other resonant frequencies of a corresponding one of the resonators.

Thereby, the number of frequency bands can be reduced. For example, 2 frequency bands, 1785 MHz to 1850 MHz and 1910 MHz to 1920 MHz are actually not used in a frequency band of 1710 MHz to 1980 MHz covering Band I, Band II, Band III, Band IV, and Band IX. Thus, in a frequency band twice the frequency band of 1710 MHz to 1980 MHz, that is, a frequency band of 3420 MHz to 3960 MHz, there is no need to suppress 2 frequency bands of 3570 MHz to 3700 MHz and 3820 MHz to 3840 MHz. Thus, the second harmonic can be further suppressed by setting resonant frequencies in a frequency band other than 3570 MHz to 3700 MHz and 3820 MHz to 3840 MHz.

Furthermore, the transmission line may include a first line formed as a microstripline, and each of the resonators may further include a second line that is formed as a microstripline and that is connected in series with a corresponding one of the capacitors.

Thereby, the matching circuit can easily adjust and generate an inductance component using microstriplines.

Furthermore, first terminals of the second lines may be connected to the connecting point, and first terminals of the capacitors may be grounded.

Thereby, the first line connected to the second lines in the resonators will improve flexibility in designing a circuit.

Furthermore, the transmission line may include a first line formed as a microstripline, and each of the resonators may further include an inductor connected in series with a corresponding one of the capacitors.

Thereby, the matching circuit can easily adjust and generate an inductance component without using a specific element.

Furthermore, one of the capacitors included in a corresponding one of the resonators may have a capacitance different from at least one of other capacitances of the other one of the capacitors of the resonators.

Thereby, one of the resonators may have a resonant frequency different from at least one of the other resonant frequencies of a corresponding one of the resonators.

Furthermore, the first line may be formed on a substrate, and the resonators may be arranged in one of areas divided by the first line formed on the substrate.

Thereby, a resonant frequency when only one of the resonators is used matches a resonant frequency when the resonators are used simultaneously, and thus such a matching circuit can be easily designed.

Furthermore, the first line may be right-angled at the connecting point, each of the resonators may be linearly arranged, a longitudinal direction of one of the resonators may be vertical to a longitudinal direction of at least the other one of the resonators, and the longitudinal directions of the resonators may be vertical to the first line.

Thereby, a mounting area of the matching circuit can be reduced. Furthermore, at least one of the resonators may be connected to the connecting point through a via.

Thereby, since a portion or entire of the resonators can be arranged in a layer different from the first line, flexibility in designing a circuit will be improved.

Furthermore, the first line may be formed on a substrate, and one of the resonators may be arranged to be symmetric to the other one of the resonators with respect to the first line.

Thereby, even when the resonators are arranged to be symmetric with each other, a resonant frequency when only one of the resonators is used matches a resonant frequency when the resonators are used together. Thus, such a matching circuit can be easily designed.

An RF power amplifier and a mobile phone each including the matching circuit of the present invention can obtain the same advantages as those of the matching circuit.

As described above, the present invention makes it possible to fabricate a matching circuit, RF power amplifier, and mobile phone whereby the second harmonic can be suppressed and the loss of the fundamental due to the self resonant frequency of the components can be reduced.

### FURTHER INFORMATION ABOUT TECHNICAL BACKGROUND TO THIS APPLICATION

The disclosure of Japanese Patent Application No. 2008-255801 filed on Sep. 30, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 illustrates a circuit structure of an RF power amplifier including an output matching circuit according to Embodiment 1 of the present invention;

FIG. 2 illustrates another circuit structure of a resonator according to Embodiment 1 of the present invention;

FIG. 3 illustrates another circuit structure of a resonator according to Embodiment 1 of the present invention;

FIG. 4 illustrates another circuit structure of a resonator according to Embodiment 1 of the present invention;

FIG. 5 shows a Smith chart representing impedances of an output matching circuit according to Embodiment 1 of the present invention;

FIG. 6 shows a graph indicating a passing characteristic of an output matching circuit according to Embodiment 1 of the present invention;

FIG. 7 illustrates a circuit structure of an RF power amplifier including an output matching circuit only including ideal elements for a comparative example;

FIG. 8 shows a Smith chart representing impedances of an output matching circuit for a comparative example;

FIG. 9 shows a Smith chart for describing a process of impedance conversion in an output matching circuit for a comparative example;

FIG. 10 shows a Smith chart for describing the next process of impedance conversion in an output matching circuit for a comparative example;

FIG. 11 shows a Smith chart for describing a process after the next process of impedance conversion in an output matching circuit for a comparative example;

FIG. 12 shows a graph indicating a passing characteristic of an output matching circuit with another circuit structure according to Embodiment 1 of the present invention;

FIG. 13 illustrates a circuit structure of an RF power amplifier including an output matching circuit according to Embodiment 2 of the present invention;

FIG. 14 illustrates a layout drawing of an output matching circuit according to Embodiment 2 of the present invention;

FIG. 15 shows a graph indicating a passing characteristic of an output matching circuit according to Embodiment 2 of the present invention;

FIG. 16 shows a graph indicating a passing characteristic when one of capacitors is removed from a resonator included in an output matching circuit according to Embodiment 2 of the present invention;

FIG. 17 shows a graph indicating a passing characteristic when a capacitor is removed from another resonator included in an output matching circuit according to Embodiment 2 of the present invention;

FIG. 18 shows a graph indicating a passing characteristic when constituent elements included in resonators included in an output matching circuit according to Embodiment 2 of the present invention have component values different from one another;

FIG. 19 illustrates another circuit structure of an RF power amplifier including a matching circuit according to Embodiment 2 of the present invention;

FIG. 20 illustrates a layout drawing of another output matching circuit according to Embodiment 2 of the present invention;

FIG. 21 shows a graph indicating a passing characteristic of another output matching circuit according to Embodiment 2 of the present invention;

FIG. 22 shows a graph indicating a passing characteristic when one of capacitors is removed from a resonator included in another output matching circuit according to Embodiment 2 of the present invention;

FIG. 23 shows a graph indicating a passing characteristic when a capacitor is removed from another resonator included in another output matching circuit according to Embodiment 2 of the present invention,

FIG. 24 shows a graph indicating a passing characteristic when constituent elements included in resonators included in another output matching circuit according to Embodiment 2 of the present invention have component values different from one another;

FIG. 25 illustrates a circuit structure of an RF power amplifier including an output matching circuit according to Embodiment 3 of the present invention;

FIG. 26 illustrates a layout drawing of an output matching circuit according to Embodiment 3 of the present invention;

FIG. 27 shows a graph indicating a passing characteristic of an output matching circuit according to Embodiment 3 of the present invention;

FIG. 28 schematically illustrates a resonance circuit including a microstripline between resonators;

FIG. 29 shows a Smith chart representing impedances of an output matching circuit when a distance between connecting points is 0.8 mm;

FIG. 30 shows a graph indicating a passing characteristic of an output matching circuit when a distance between connecting points is 0.8 mm;

FIG. 31 shows a Smith chart representing impedances of an output matching circuit when a distance between connecting points is 1.0 mm;

FIG. 32 shows a graph indicating a passing characteristic of an output matching circuit when a distance between connecting points is 1.0 mm;

FIG. 33 illustrates a perspective view of a mobile phone;

FIG. 34 illustrates a circuit structure of a conventional multiband matching circuit; and

FIG. 35 illustrates a circuit structure of an RF power amplifier including a conventional output matching circuit.

### DESCRIPTION OF THE PREFERRED EMBODIMENTS

Embodiments of matching circuits as aspects of the present invention will be described with reference to drawings. The same constituent elements are denoted by the same numerals, and the same functions and advantages to be described for the constituent elements will not be repeated.

### Embodiment 1

A matching circuit according to Embodiment 1 of the present invention includes a transmission line through which a radio-frequency signal is transmitted, and resonators. Each of the resonators includes a capacitor, first terminals of the resonators are connected to substantially a same connecting point, and the other terminals that are second terminals of the resonators are grounded.

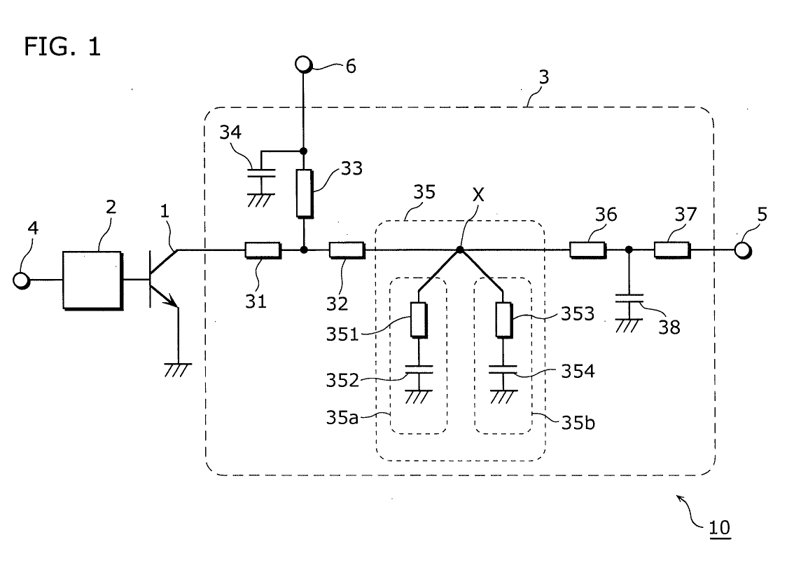

FIG. 1 illustrates a circuit structure of an RF power amplifier including a matching circuit according to Embodiment 1 of the present invention.

An RF power amplifier 10 in FIG. 1 is a broadband amplifier in which impedances in a frequency band ranging from 1710 MHz to 1980 MHz (referred to as the fundamental herein) match. The RF power amplifier 10 includes an input matching circuit 2, an amplification transistor 1, an output matching circuit 3, an input terminal 4, an output terminal 5, and a power supply voltage terminal 6.

The input matching circuit 2 is a circuit for matching an impedance of a transmission line connected to the input terminal 4 to an impedance of the amplification transistor 1 at the next stage.

The input terminal 4 supplies, to the amplification transistor 1, a radio-frequency signal in which the impedances are matched by the input matching circuit 2. The power supply voltage terminal 6 supplies current to the amplification transistor 1 through the output matching circuit 3. Then, the amplification transistor 1 amplifies the radio-frequency signal and transmits the amplified signal to the output matching circuit 3. Here, the amplification transistor 1 may be any one of a Field effect transistor (FET) and a Bipolar Junction Transistor (BJT). The amplification transistor 1 in Embodiment 1 is described as a BIT.

The output matching circuit 3 is a circuit for matching the impedance of the amplification transistor 1 to the impedance of the output terminal 5. More specifically, the output matching circuit 3 includes microstriplines 31, 32, 33, 36, and 37, a bypass capacitor 34, a resonance circuit 35, and a capacitor 38.

A terminal of the microstripline 31 is connected to a collector terminal of the amplification transistor 1, and the other terminal of the microstripline 31 is connected to a terminal of the microstripline 32 and to a terminal of the microstripline 33 that supplies power supply voltage and is for bias. The other terminal of the microstripline 33 is connected to the power supply voltage terminal 6 and a terminal of the bypass capacitor 34. Furthermore, the other terminal of the bypass capacitor 34 is grounded. Furthermore, the other terminal of the microstripline 32 is connected to the resonance circuit 35 at a branch point X.

The resonance circuit 35 is a circuit that resonates at a frequency twice the frequency of the fundamental to shunt the second harmonic. The resonance circuit 35 is connected to the microstriplines 32 and 36 at the branch point X. More specifically, the resonance circuit 35 includes a resonator 35a and a resonator 35b each of which is connected to the branch point X. More specifically, in the resonator 35a, a microstripline 351 is connected in series with a terminal of a capacitor 352, and the other terminal of the capacitor 352 is grounded. Furthermore, a structure of the resonator 35b is the same as that of the resonator 35a. Furthermore, the branch point X is identical to a connecting point in the description.

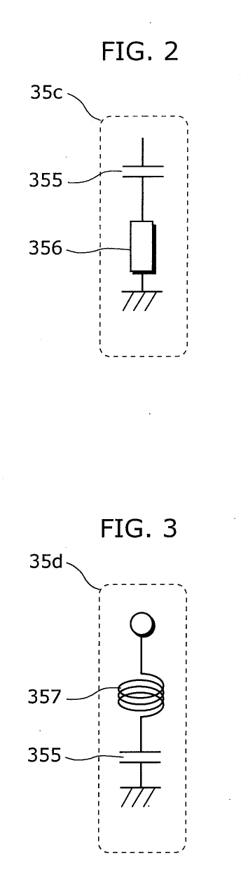

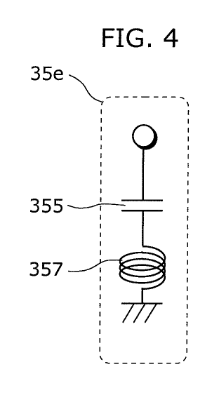

Here, each of the microstriplines included in the output matching circuit 3 in FIG. 1 can be replaced with an inductor. Furthermore, each of the resonator 35a and the resonator 35b may be replaced with a resonance circuit 35c including a microstripline 356 and a capacitor 355 as illustrated in FIG. 2. Furthermore, each of the resonator 35a and the resonator 35b may be replaced with: a resonance circuit 35d including an inductor 357 as a replacement for the microstripline 351 and the microstripline 353 as illustrated in FIG. 3; and a resonance circuit 35e including the inductor 357 that is grounded as illustrated in FIG. 4.

The terminal of the microstripline 36 that is not connected to the resonance circuit 35 is connected to the microstripline 37 that is a transmission line for output and to the capacitor 38. The microstripline 37 and the capacitor 38 shunt the third harmonic having a bandwidth triple a bandwidth of the fundamental. More specifically, a terminal of the capacitor 38 is grounded, and the other terminal of the capacitor 38 is connected to a terminal of the microstripline 37, and the other terminal of the microstripline 37 is connected to the output terminal 5.

What is described hereinbefore is the structure of the RF power amplifier 10 including the output matching circuit 3. Component values and characteristics of each component included in the output matching circuit 3 will be described hereinafter.

First, the input impedance and the output impedance of the output matching circuit 3 will be described.

The input impedance is calculated from a required output power and an applied voltage of the amplification transistor 1. First, the required output power is determined based on the GSM standard that requires the highest output. The output power of an antenna terminal should be equal to or smaller than 30 dBm under the GSM standard. A general structure of a connection path from an antenna to the amplification transistor 1 includes a switch for the antenna, a lowpass filter, and the output matching circuit 3 approximately having losses of 0.5 dB, 0.5 dB, and 1.0 dB, respectively. Furthermore, 33 dBm including a margin of 1 dB is required as the output power of the amplification transistor 1 so that output from the antenna terminal always satisfies 30 dBm in consideration of the variations of each component and a degradation characteristic due to temperature change.

Next, assuming that a starting voltage of a battery that supplies power to the amplification transistor 1 is 3.5 V, and a sum of (i) a voltage drop of a control circuit for controlling a power supply voltage on the connection path and (ii) a voltage drop of a conductor on the connection path is 0.3 V, 3.2 V is applied to the amplification transistor 1. The input impedance estimated under these two conditions is approximately 50 ohm.

Furthermore, the output impedance is assumed to be 50 ohm that is generally used as an impedance for radio-frequency engineering.

The component values of each component included in the output matching circuit 3 are determined as follows to satisfy the aforementioned conditions for the input impedance and the output impedance.

Here, the microstripline 31 had a width of 200 μm and a length of 0.57 mm. The microstripline 32 had a width of 200 μm and a length of 1.0 mm. The microstripline 33 for bias had a width of 150 μm and a length of 9.0 mm. A 0603 surface mount device (SMD) chip component was used as the bypass capacitor 34, and had a capacitance of 100 pF. The microstripline 36 had a width of 200 μm and a length of 5.7 mm. The microstripline 37 had a width of 200 μm and a length of 0.3 mm. Another 0603 SMD chip component was used as the capacitor 38, and had a capacitance of 2.3 pF. The microstriplines 351 and 353 had a width of 200 μm and a length of 0.5 mm. The other 0603 SMD chip components were used as the capacitors 352 and 354, and had a capacitance of 3.5 pF.

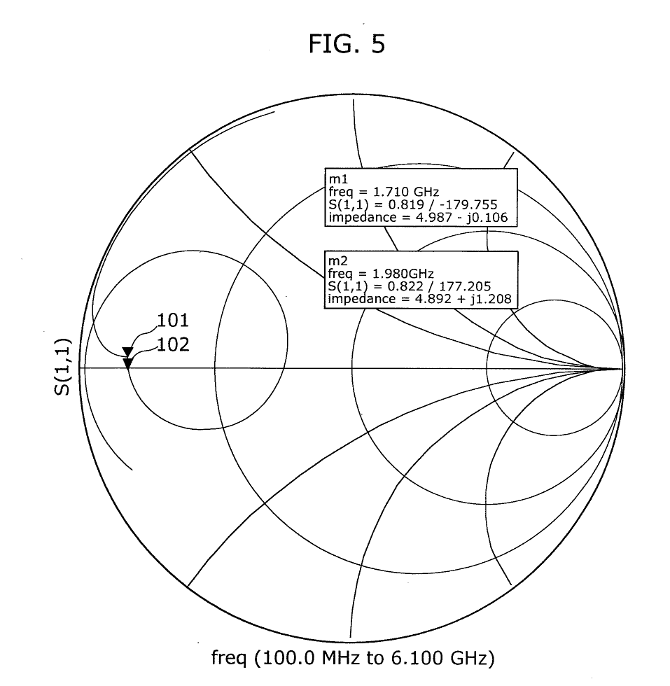

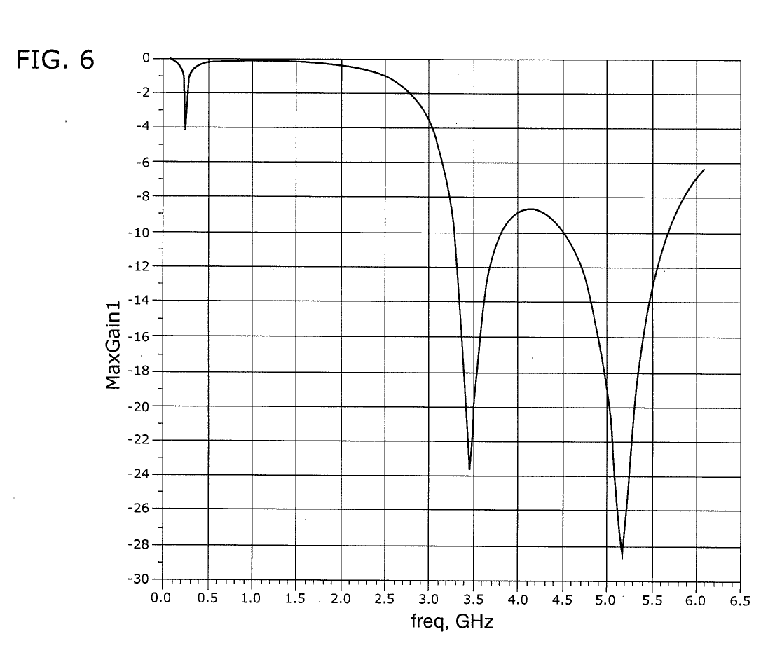

FIG. 5 shows a Smith chart representing impedances of the output matching circuit 3 according to Embodiment 1. Furthermore, FIG. 6 shows a graph indicating a passing characteristic of the output matching circuit 3. Maximum Available power Gain is represented as the passing characteristic of the output matching circuit 3 on the vertical axis of FIG. 6.

In FIG. 5, an impedance 101 at 1710 MHz and an impedance 102 at 1980 MHz are approximately 50 ohm, indicating that impedances in a frequency band between 1710 MHz and 1980 MHz are approximately 50 ohm. Furthermore, FIG. 6 shows that the resonance circuit 35 that shunts the second harmonic resonates at 3.45 GHz, and that the impedances are matched approximately in a frequency band (3420 MHz to 3960 MHz) that is twice the bandwidth of the fundamental.

An output matching circuit including the resonance circuit 35 including one resonator will hereinafter be described in comparison with Embodiment 1.

### Comparison Example

An output matching circuit according to the conventional technique was examined in comparison with that of the present invention.

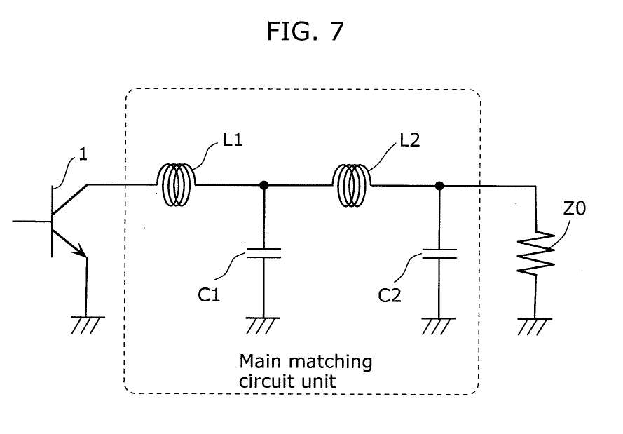

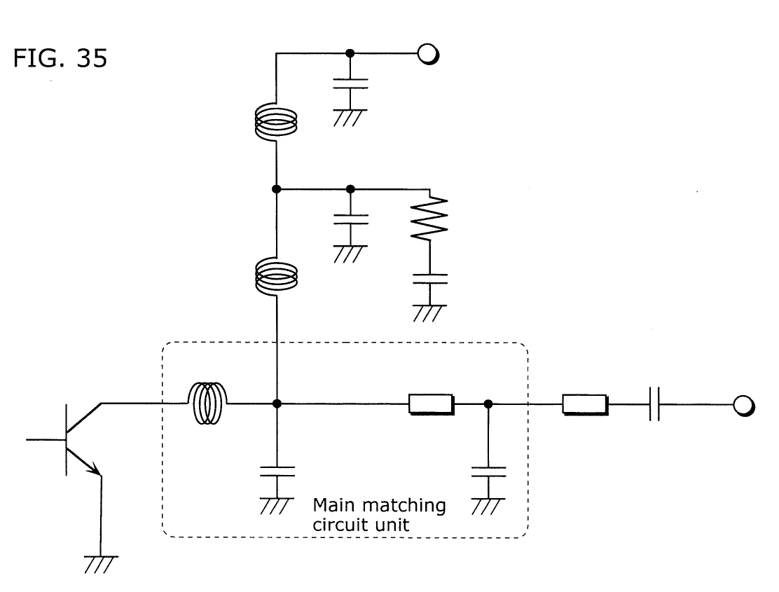

FIG. 7 illustrates a circuit diagram that is a simplified diagram of the main matching circuit unit in FIG. 35 and that includes only inductors and capacitors as an example of the conventional output matching circuit. The impedance of a radio-frequency signal becomes smaller under the assumption that a capacitor that is for DC elimination and is connected to an output terminal of the main matching circuit unit in FIG. 35 has a sufficiently large capacitance. Thus, FIG. 7 omits other elements that are ideal elements and include neither parasitic capacitor, parasitic inductor, nor parasitic resistor.

The output impedance of the main matching circuit unit needs to be limited to no larger than 50 ohm that is a value in which characteristic impedance is independent of frequencies in a 50-ohm matched circuit, as a condition for widening a bandwidth in FIG. 7. When the main matching circuit unit in FIG. 7 converts a signal having the fundamental frequency to an impedance, the input impedance needs to be set between 1710 MHz and 1980 MHz that are respectively the lower limit and the upper limit of the fundamental frequency. As described in Embodiment 1, the input impedance is 50 ohm. Here, the elements in the main matching circuit unit were examined so that the output impedance of 50 ohm matches the input impedance of 50 ohm.

Here, the result of our examination shows that a capacitor C2 had a capacitance of 2.86 pF, an inductor L2 had an inductance of 2.51 nH, a capacitor C1 had a capacitance of 10.22 pF, and an inductor L1 had an inductance of 0.7 nH, as component values.

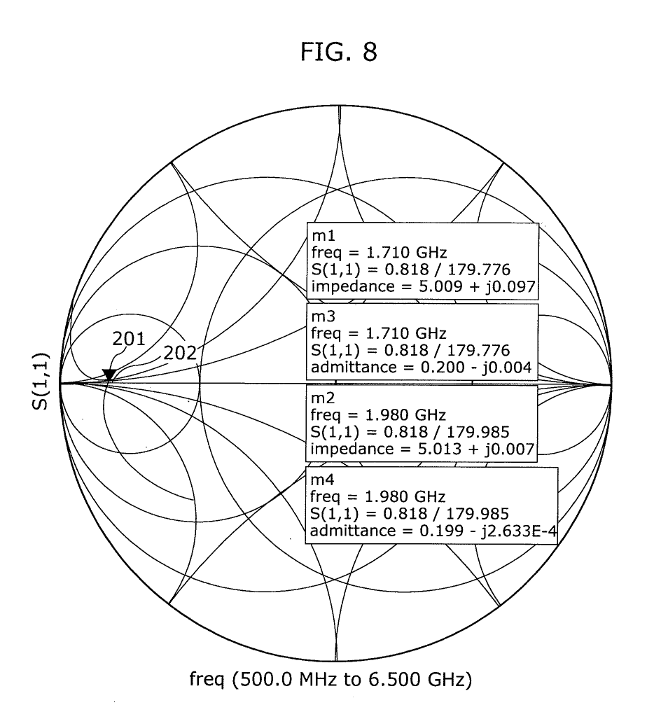

FIG. 8 shows a Smith chart representing impedances of the output matching circuit for a comparative example. In FIG. 8, an impedance 201 at 1710 MHz and an impedance 202 at 1980 MHz are approximately 50 ohm. Thus, the impedances also match in FIG. 8.

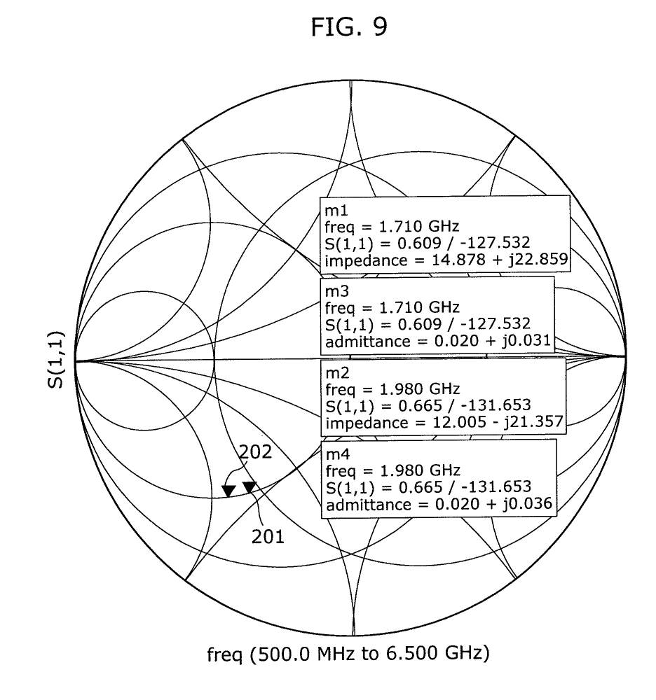

Most noteworthy is that the capacitor C1 had a capacitance of 10.22 pF that is a larger value. In the case of matching impedances at a single frequency, there is no problem that the capacitor C1 has a smaller value. However, when the impedances over the wider bandwidth are adjusted to be an identical impedance and the capacitor C1 has a smaller value, the impedances cannot be matched. Thus, the capacitance needs to have a larger value. The reasons will be described with reference to FIGS. 9, 10, and 11.

FIG. 9 shows a Smith chart of joint impedances of (i) an output impedance ZO in FIG. 7 and (ii) the impedance of the capacitor C2 that is grounded. Since the output impedance ZO is independent of frequencies, the impedance is converted according to a frequency of the capacitor C2 that is grounded. The obtained impedances as a result of the conversion vary when a real part of an admittance is constant.

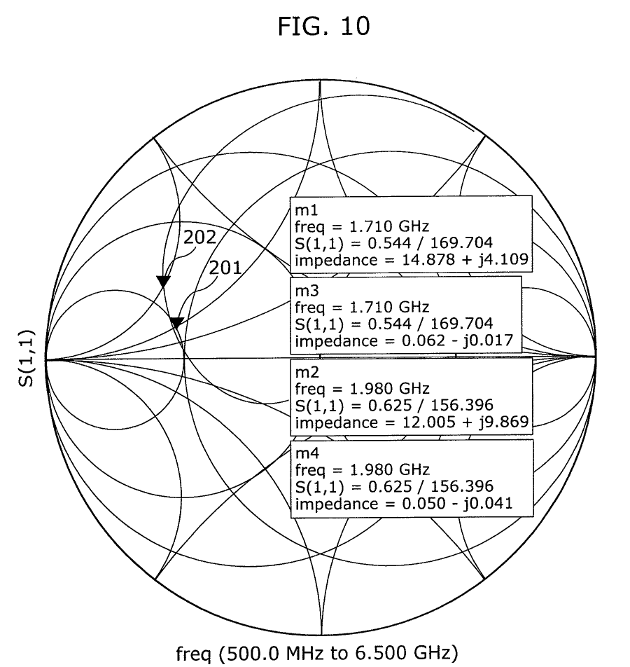

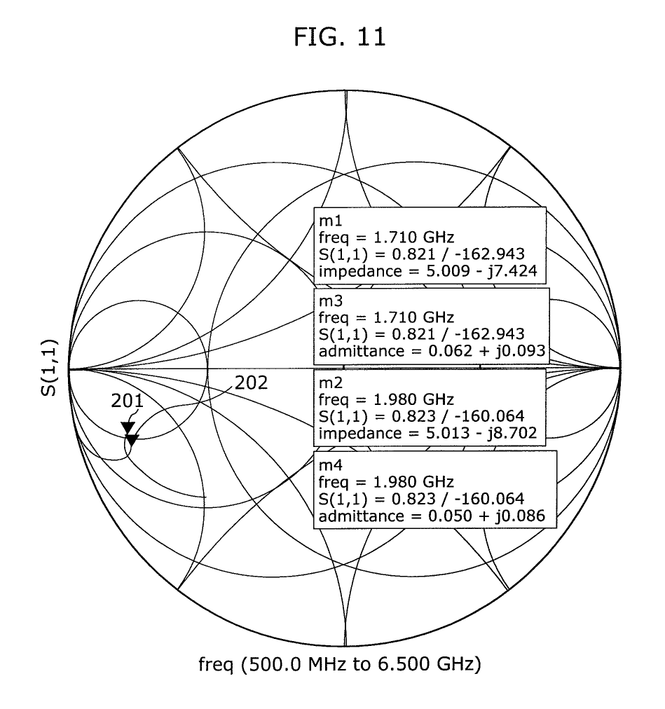

Next, FIG. 10 shows a Smith chart representing impedances of an output matching circuit obtained by adding the inductor L2 to the output matching circuit described with reference to FIG. 9 so that the inductor L2 is connected in series. The obtained impedances as a result of a conversion vary when a real part of an impedance is constant. The structures of circuits described hereinbefore offer the user a choice of designing the main matching circuit unit over a wider bandwidth. Here, as a condition for the wider bandwidth, a real part of an admittance in a higher frequency need to be smaller than that of an admittance in a lower frequency. This is because the capacitor C1 that is an impedance conversion element and is connected next to the inductor L2 is grounded, and thus the real part of the admittance is constant as shown in FIG. 11. Furthermore, the inductor L1 is next connected to the capacitor C1, and thus a capacitive impedance in a higher frequency becomes larger than a capacitive impedance in a lower frequency. In other words, since a real part of an admittance in the capacitor C1 is constant, the real part of admittance in its radio-frequency circuit needs to become larger in the circuit including the capacitor C2 and the inductor L1. Here, a capacitance of the capacitor C1 becomes larger, because the impedance of the inductor L2 is converted to a larger inductive impedance. Furthermore, the capacitive impedance is converted to a larger inductive impedance in FIG. 10, because the impedance having a larger real part is in a frequency lower than a frequency of the impedance having a smaller real part in FIG. 9.

Thus, when an impedance is converted using the inductor L2, an admittance having a real part in a higher frequency is converted to an impedance having a smaller real part in a capacitive impedance region. Conversely, when an impedance is converted to a inductive impedance, an imaginary part of the impedance reverses in sign, and the real part of the admittance becomes larger.

In this way, since the impedance of the capacitor C1 is converted to a lower impedance, the impedance needs to have a larger value obtained by the impedance conversion to cover an inductive region to a capacitive region. Furthermore, as wider a frequency band in which impedances match is, the capacitor C1 needs to have a larger capacitance.

However, there is a problem in a larger capacitance of the capacitor C1 when an output matching circuit is actually fabricated.

Currently, SMD chip components each with a length of 0.6 mm, a width of 0.3 mm, and a height of 0.3 mm are mainly used as components of matching circuits for RF power amplifiers. However, these components normally have parasitic inductance due to each physical length. For example, when a capacitor that is numbered GRM0332C1E100JD01 of Murata Manufacturing Co., Ltd. and has a capacitance of 10 pF is used as the capacitor C1, the capacitor had a self resonant frequency of 2.33 GHz.

Furthermore, when such a chip component is connected on a dielectric substrate, there is a possibility that another parasitic inductance will occur through a connection path to the ground, and the chip component will resonate at a frequency lower than 2.33 GHz. Here, since the self resonant frequency is close to a frequency band of 1710 MHz to 1980 MHz that is the frequency band for the fundamental, the loss of the fundamental increases and the efficiency of the RF power amplifiers is sharply reduced.

In contrast, the output matching circuit 3 of Embodiment 1 includes resonators each including a capacitor as a replacement for the capacitor C1 of the resonance circuit 35 in FIG. 7, and thus the capacitors 352 and 354 had smaller capacitances. Thereby, the self resonant frequency of the capacitors 352 and 354 became too high to be subject to the bandwidth of the fundamental, and the resonance circuit 35 had the resonant frequency within a bandwidth twice the bandwidth of the fundamental.

As described above, the output matching circuit 3 of Embodiment 1 can suppress the second harmonic and reduce the loss of fundamental due to the self resonant frequency of the components.

Here, the resonators included in the resonance circuit 35 may be 3 or more to match frequencies in a wider bandwidth.

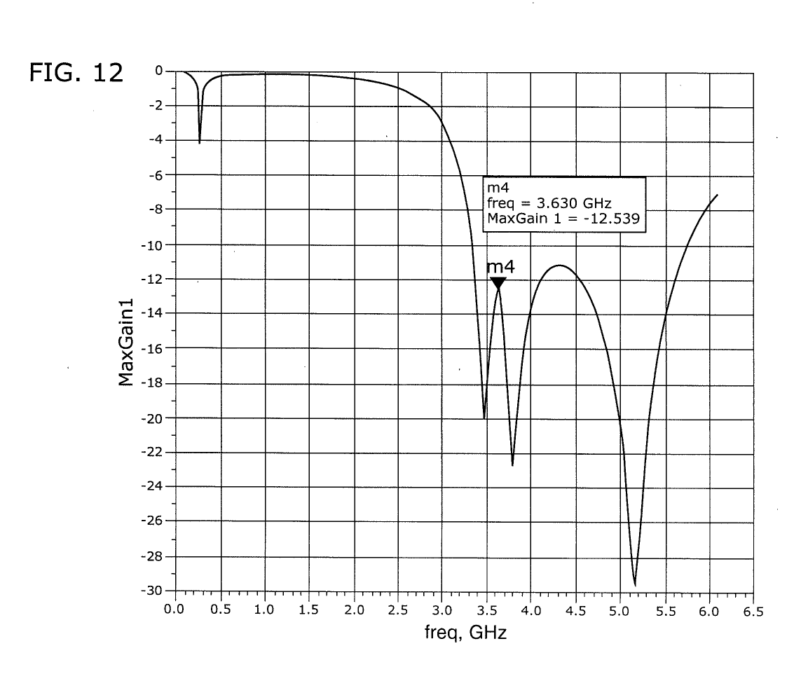

Furthermore, resonators included in the resonance circuit 35 may be configured to resonate at different frequencies in a frequency band twice the bandwidth of the fundamental, so that the second harmonic can be suppressed as an application of the structure according to an aspect of the present invention. As an example, FIG. 12 shows a passing characteristic when, in the resonator 35a of the resonance circuit 35 in FIG. 1, the microstripline 351 has a length of 0.3 mm, the capacitor 352 has a capacitance of 4 pF, the microstripline 352 of the resonator 35b has a length of 0.46 mm, the capacitor 354 has a capacitance of 3 pF, and other components included in the output matching circuit 3 have the same component values as described above. Here, while the resonant frequency of the resonator 35a is adjusted to 3.45 GHz, the resonant frequency of the resonator 35b is adjusted to 3.8 GHz. Although the frequency band to be amplified is in a frequency band of 1710 MHz to 1980 MHz, 2 frequency bands of 1785 MHz to 1850 MHz and 1910 MHz to 1920 MHz are not used therein, and the second harmonic is not generated in 2 frequency bands twice the aforementioned frequency bands, that is, 3570 MHz to 3700 MHz and 3820 MHz to 3840 MHz. Thus, there is no need to set larger attenuation in these frequency bands in a resonator. Here, the frequency band of 3820 MHz to 3840 MHz is very narrow, and thus the difficulty lies in adjustment of the attenuation. In contrast, the other frequency band of 3570 MHz to 3700 MHz has a wider bandwidth of 130 MHz. In other words, a resonator adjusted to give a frequency band equal to or lower than 3570 MHz and a resonator adjusted to give a frequency band equal to or larger than 3700 MHz can efficiently suppress the second harmonic.

### Embodiment 2

Embodiment 2 embodies a layout of the output matching circuit according to Embodiment 1.

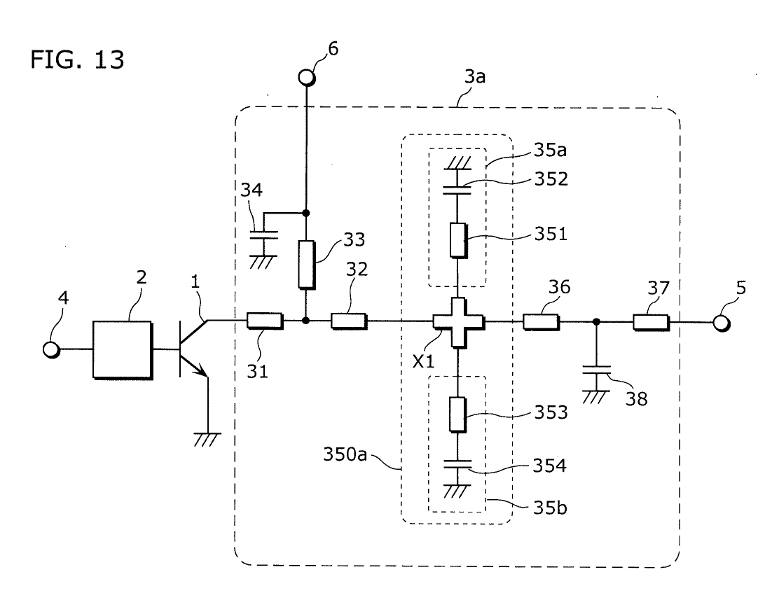

FIG. 13 illustrates a circuit structure of an RF power amplifier including an output matching circuit according to Embodiment 2 of the present invention. FIG. 13 differs from FIG. 1 in that a shape of the branch point X is embodied to a shape of a branch point X1. The following mainly describes the branch point X1.

The branch point X1 in FIG. 13 is made up of a microstripline having 4 sides as connection terminals. The microstriplines 32 and 36 are respectively connected to the connection terminals that are symmetric with respect to the branch point X1, and the resonators 35a and 35b are also respectively connected to the other connection terminals that are symmetric with respect to the branch point X1. Furthermore, component values of each constituent element in FIG. 13 are the same as those in FIG. 1.

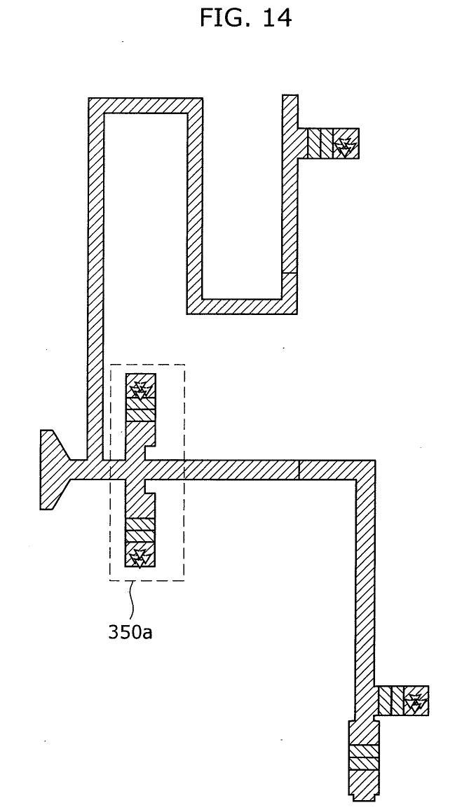

FIG. 14 illustrates a layout drawing when the output matching circuit 3a in FIG. 13 is actually laid out.

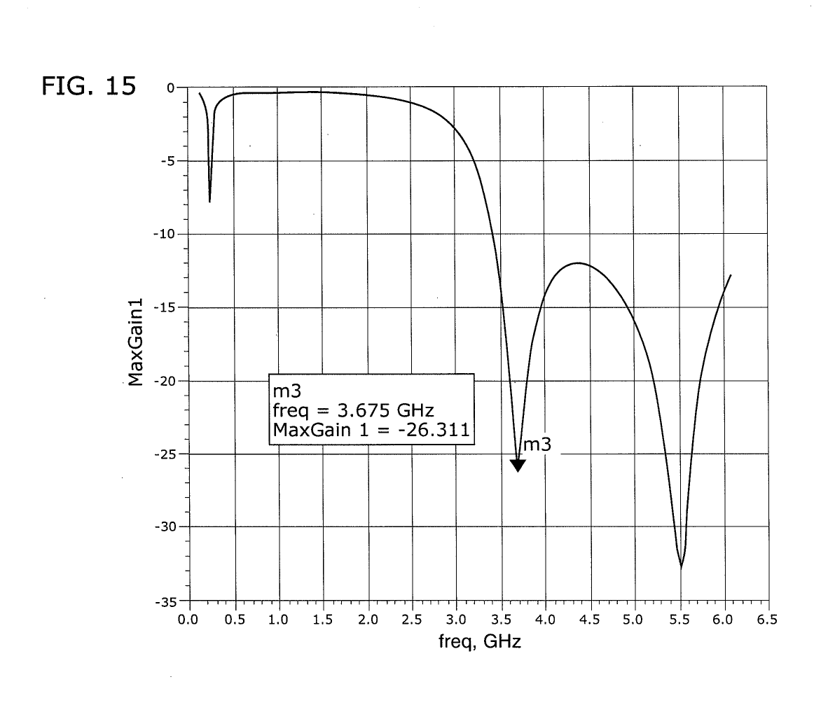

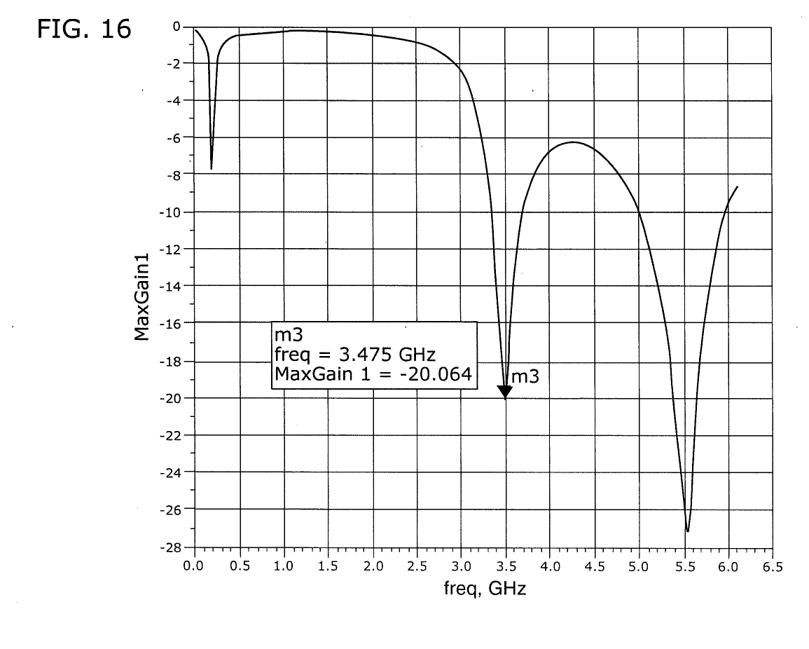

FIG. 15 shows a graph indicating a passing characteristic as a result of electromagnetic field analysis on the output matching circuit 3a in the layout drawing of FIG. 14. The passing characteristic in FIG. 15 shows that a resonant frequency of a resonance circuit 350a is 3.675 GHz. However, the capacitor 354 is removed from the resonator 35b of the resonance circuit 350a so that a terminal of the microstripline 353 is open. When a resonant frequency of the resonance circuit 350a with only the resonator 35a and the microstripline 353 is calculated, the resonant frequency becomes 3.475 GHz as shown in FIG. 16.

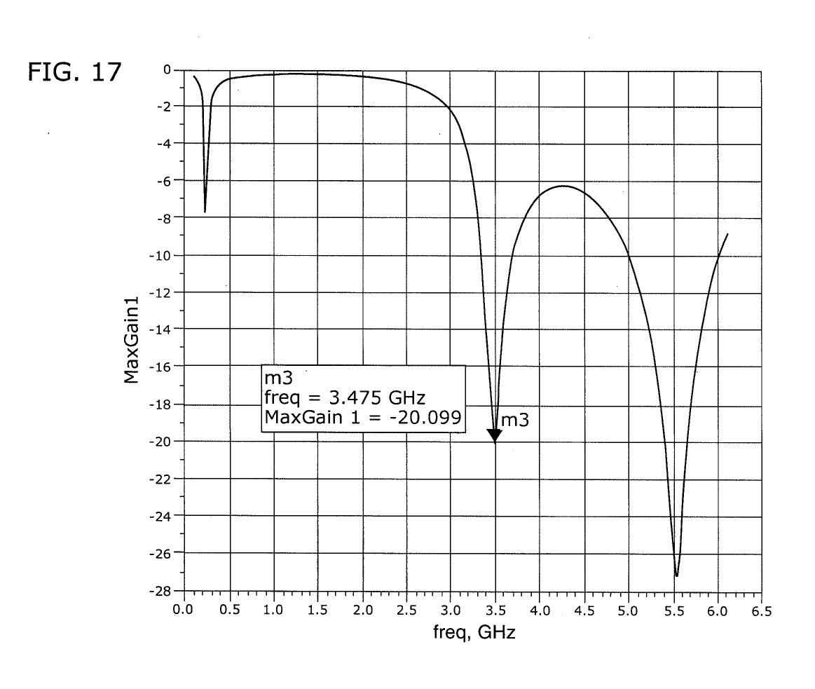

Similarly, the capacitor 352 is removed from the resonator 35a of the resonance circuit 350a so that a terminal of the microstripline 351 is open. When a resonant frequency of the resonance circuit 350a with only the resonator 35b and the microstripline 351 is calculated, the resonant frequency becomes 3.475 GHz as shown in FIG. 17.

Although the resonance circuit 350a in FIG. 13 only includes the resonators 35a and 35b, the difficulty lies in designing the resonance circuit 350a to give a desirable frequency. This is because the combination of 2 resonators causes a frequency deviation having a resonant frequency different from each of the resonant frequencies of the resonators 35a and 35b.

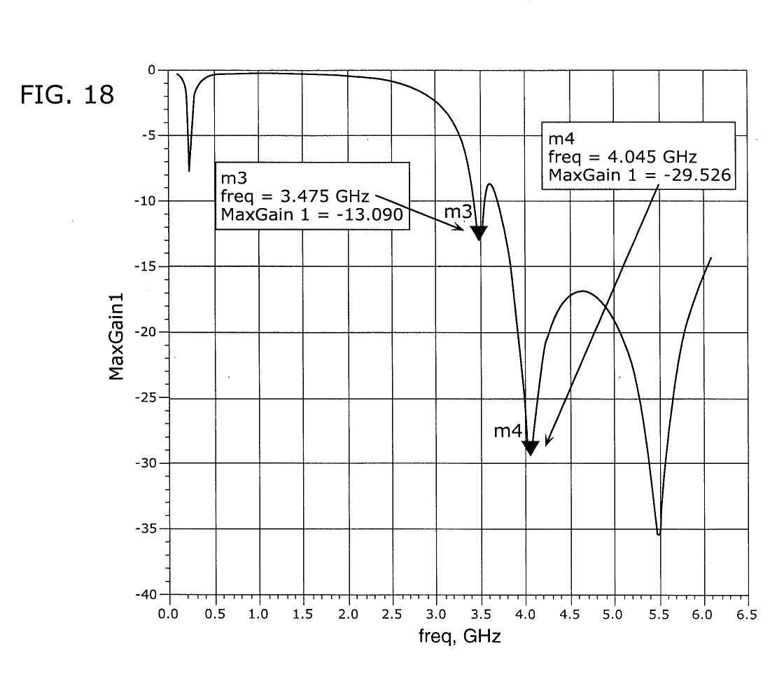

FIG. 18 shows a graph indicating a passing characteristic when the constituent elements included in one of the resonators 35a and 35b of the resonance circuit 350a have component values different from those of constituent elements in the other of the resonators 35a and 35b in FIG. 13.

In the resonator 35a of the resonance circuit 350a, the microstripline 351 had a length of 0.3 mm, the capacitor 352 had a capacitance of 3.8 pF, the microstripline 353 of the resonator 35b had a length of 0.3 mm, and the capacitor 354 had a capacitance of 3.2 pF. FIG. 18 shows that the resonant frequencies are 3.475 GHz and 4.045 GHz. Here, an attenuation at the resonant frequency of 3.475 GHz is 13 dB that is smaller. Furthermore, an attenuation at a frequency of 3.600 GHz that is a frequency including a second harmonic is 8.6 dB. Thus, a difficulty lies in completely suppressing the second harmonic.

Furthermore, under these conditions, a resonant frequency of the resonator 35a alone is 3.580 GHz, while a resonant frequency of the resonator 35b alone is 3.900 GHz. These values are deviated from a resonant frequency calculated with the combination of the resonators 35a and 35b by equal to or larger than 100 MHz, and thus a difficulty lies in designing the resonance circuit 350a to give a desirable frequency.

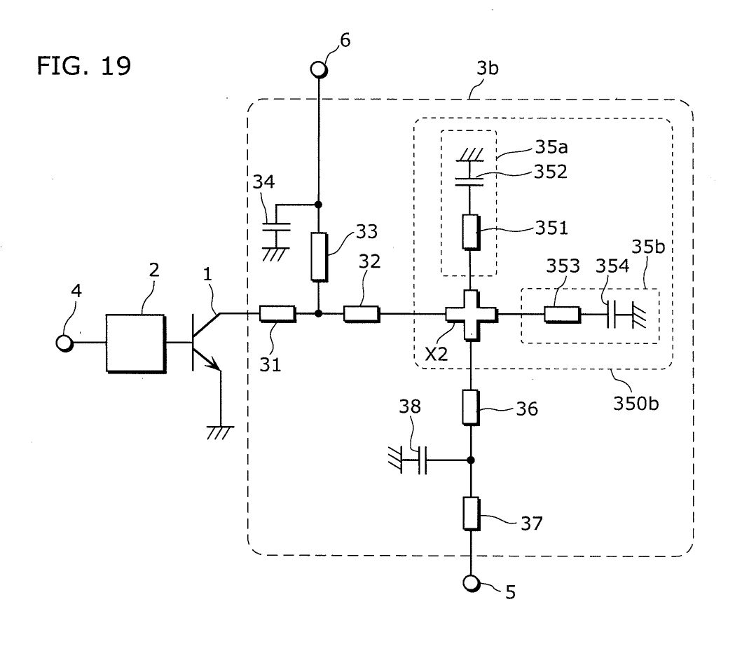

FIG. 19 illustrates another circuit structure of the RF power amplifier including the output matching circuit according to Embodiment 2 of the present invention. FIG. 19 differs from FIG. 13 in that the shape of the branch point X1 is changed to a shape of a branch point X2. The following mainly describes differences between the branch point X1 and the branch point X2.

The branch point X2 in FIG. 19 is made up of a microstripline having 4 sides as connection terminals. The microstriplines 32 and 36 are respectively connected to the connection terminals that are adjacent to each other with respect to the branch point X2, and the resonators 35a and 35b are respectively connected to the other connection terminals that are adjacent to each other with respect to the branch point X2. Furthermore, component values of each constituent element in FIG. 19 are the same as those in FIG. 1.

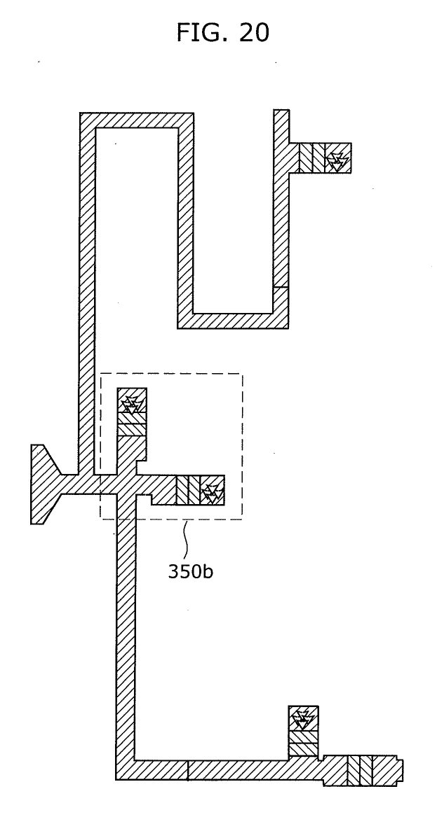

FIG. 20 illustrates a layout drawing when the output matching circuit 3b in FIG. 19 is actually laid out.

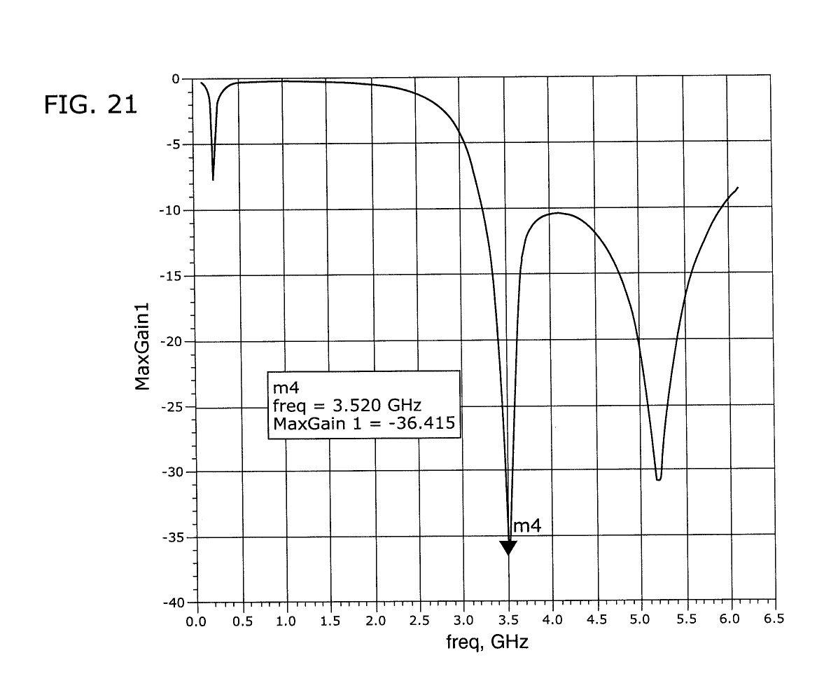

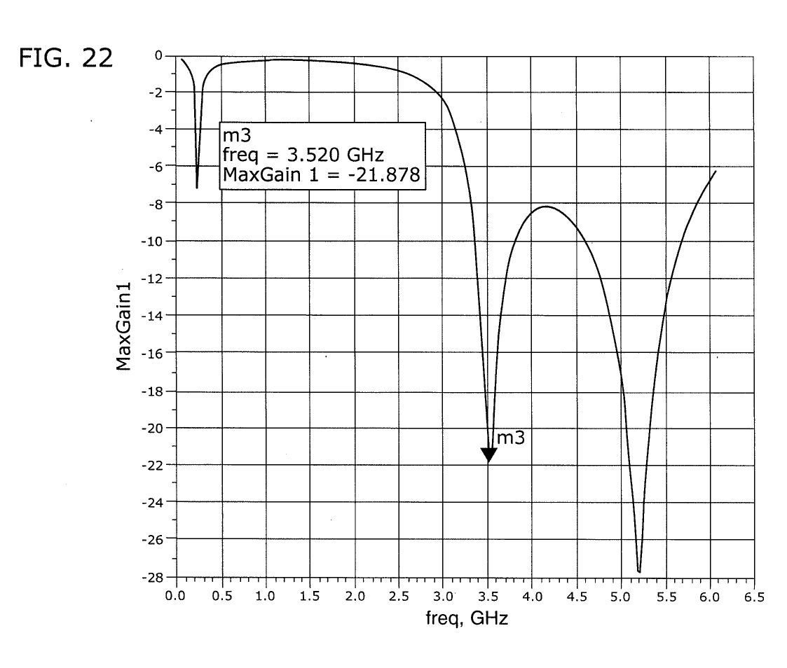

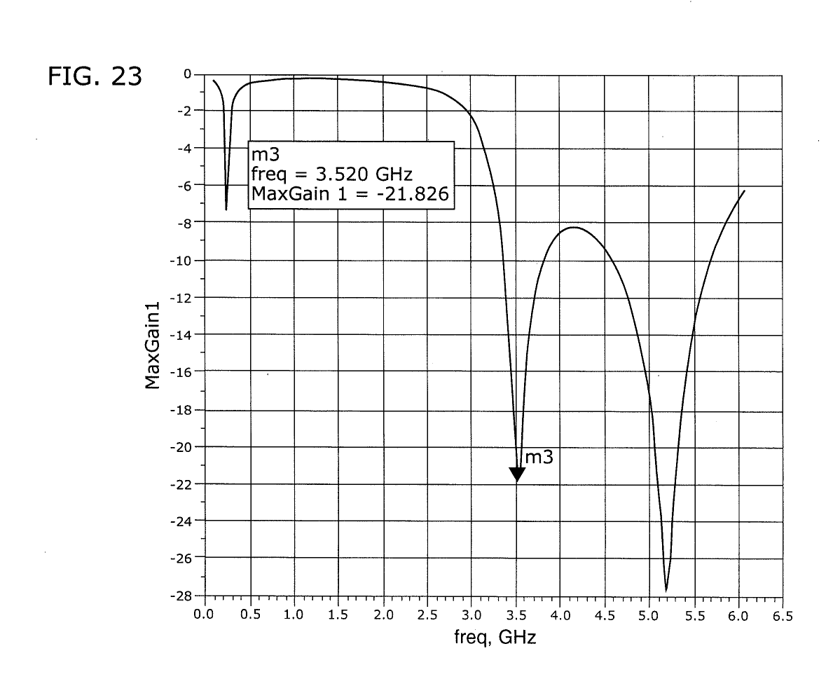

FIG. 21 shows a graph indicating a passing characteristic as a result of electromagnetic field analysis on the output matching circuit 3b in the layout drawing of FIG. 20. The passing characteristic in FIG. 21 shows that a resonant frequency of a resonance circuit 350b is 3.52 GHz. Furthermore, the capacitor 354 is removed from the resonator 35b of the resonance circuit 350b so that a terminal of the microstripline 353 is open. When a resonant frequency of the resonance circuit 350b with only the resonator 35a and the microstripline 353 is calculated, the resonant frequency becomes 3.52 GHz as shown in FIG. 22. Similarly, the capacitor 352 is removed from the resonator 35a of the resonance circuit 350b so that a terminal of the microstripline 351 is open. When a resonant frequency of the resonance circuit 350b with only the resonator 35b and the microstripline 351 is calculated, the resonant frequency becomes 3.52 GHz as shown in FIG. 23.

Thus, the resonators 35a and 35b can resonate at an identical frequency in the resonance circuit 350b in FIG. 19.

Furthermore, similarly as the application of Embodiment 1, resonators included in the resonance circuit 350b are resonated at different frequencies in a frequency band including the second harmonic to suppress the second harmonic over a wider bandwidth.

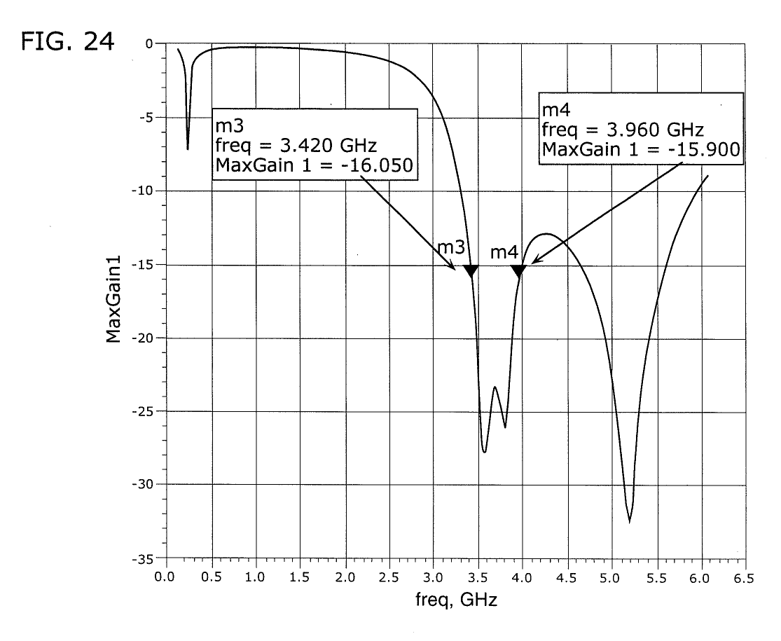

FIG. 24 shows a graph indicating a passing characteristic of the output matching circuit 3b when the constituent elements included in one of the resonators 35a and 35b of the resonance circuit 350b have component values different from those of constituent elements in the other one of the resonators 35a and 35b in FIG. 19.

In the resonator 35a, the capacitor 352 had a capacitance of 3.2 pF and the microstripline 351 had a length of 0.4 mm while in the resonator 35b, the capacitor 354 had a capacitance of 3.8 pF and the microstripline 353 had a length of 0.36 mm. FIG. 24 shows an attenuation equal to or larger than 15.9 dB in a frequency band of 3420 MHz to 3960 MHz that is twice the bandwidth of the fundamental. Thus, power in such a frequency band can be attenuated over a wider bandwidth.

Thus, the resonator 35a is desirably adjacent to the resonator 35b in the resonance circuit 350b as illustrated in FIG. 19 so as to embody the circuit structure in FIG. 1. More specifically, what is desired is that (i) a first line including the microstriplines 32 and 36 is right-angled at the branch point X2, (ii) each of the resonators 35a and 35b is linearly arranged, (iii) a longitudinal direction of one of the resonators 35a and 35b is vertical to a longitudinal direction of the other one of the resonators 35a and 35b, and (IV) each of the longitudinal directions of the resonators 35a and 35b is vertical to the first line and 35b is vertical to the first line.

Here, arranging the resonators in one of areas divided by a transmission line provided on a substrate may have the same advantage as described above.

### Embodiment 3

Embodiment 3 is another embodiment for embodying a layout of the output matching circuit according to Embodiment 1, and one of resonators included in the output matching circuit is arranged to be symmetric to the other one of the resonators with respect to the first line.

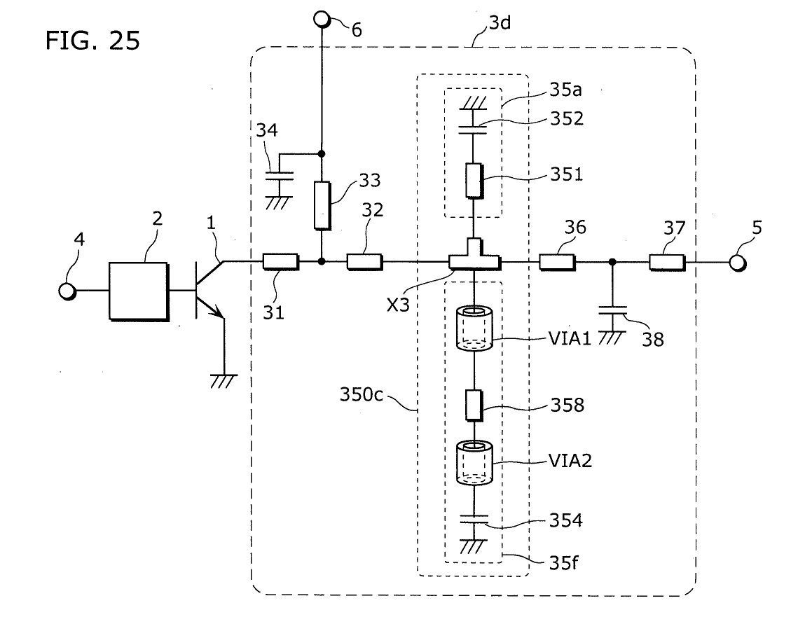

FIG. 25 illustrates a circuit structure of an RF power amplifier including an output matching circuit 3d according to Embodiment 3 of the present invention. A branch point X3 in FIG. 25 includes 4 connection terminals made up of (i) a T-shaped or Y-shaped microstripline having 3 sides and (ii) a via hole VIA 1 to be connected to a microstripline 358 formed on a different dielectric layer. The microstriplines 32 and 36 are connected to any one of 3 connection terminals of the microstripline, the resonator 35a is connected to the remaining side of the branch point X3, and a resonator 35f is connected to the via hole VIA 1 of the branch point X3.

The resonator 35f is connected in series with the via hole VIA 1, the microstripline 358, a via hole VIA 2, and the capacitor 354 having a terminal grounded. The other structure is the same as that of FIG. 1, and thus the description is omitted.

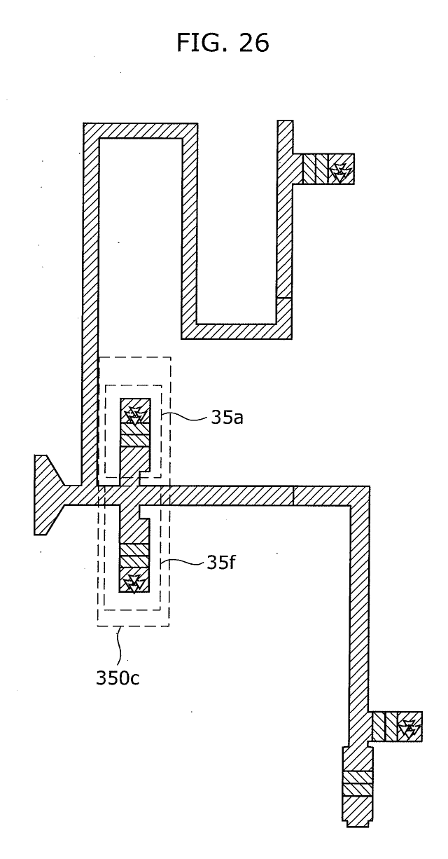

FIG. 26 illustrates a layout drawing of the output matching circuit 3d of Embodiment 3. A resonance circuit 350c in FIG. 26 includes the resonator 35a that is connected to a layer including a metal line that is a signal line of the microstripline of the branch point X3 and that has the same circuit structure as that of the resonator 35a of Embodiment 2. In contrast, the branch point X3 is connected to the microstripline 358 that is arranged on a back side of the microstripline of the branch point X3 through the via hole VIA 1 having a height of 100 μm, and the microstripline 358 is connected to the capacitor 354 through the via hole VIA 2 in the resonator 35f. Since the resonator 35a has a circuit structure identical to that of the resonator 35a in Embodiment 2, the resonant frequency is 3.52 GHz. The length of the microstripline 358 is adjusted so that the resonant frequency of the resonator 35f can resonate at 3.52 GHz that is the same frequency as that of the resonator 35a. Here, component values of each constituent element in FIG. 26 are the same as those in FIG. 1

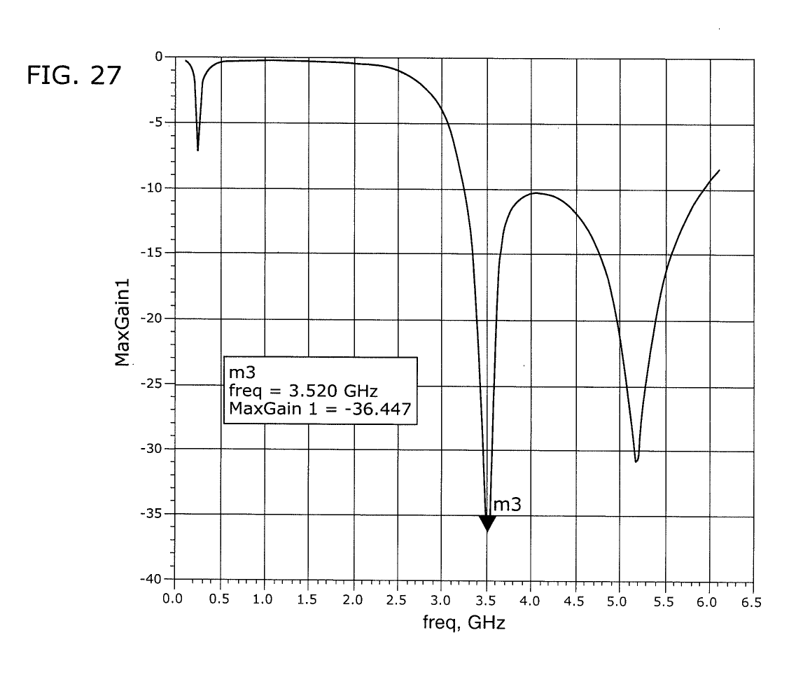

FIG. 27 shows that the resonant frequency of the resonance circuit 350c is 3.52 GHz, as a result of the electromagnetic field analysis on the output matching circuit in FIG. 26 and calculation of the passing characteristic. As such, one resonator is connected to the branch point X3 through a via hole. Thereby, even when the resonators 35a and 35f included in the resonator 350c are symmetrically arranged with respect to a transmission line of the branch point X3, the resonators 35a and 35f can have a resonant frequency identical to that of the resonance circuit 350c.

Here, when one resonator is connected to a branch point through a via hole, a pair of resonators including the one resonator and included in a resonance circuit may be laid out so as to be adjacent to each other without being separated by a transmission line. Furthermore, the microstripline 358 may be replaced with a transmission line that is formed as a strip line arranged in a dielectric layer lower than the microstripline 351. Furthermore, a portion of a resonator may be formed as a strip line and another portion of the resonator may be formed as a microstripline.

The component values of the resonators 35a and 35b are adjusted so that the resonators 35a and 35b resonate at different frequencies in a frequency band including the second harmonic as an application of the above circuit structure. Thereby, the second harmonic can be suppressed over a wider bandwidth.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

For example, the branch point X desirably includes: a first connecting point connected to the center of an edge of the second line included in the first resonator out of resonators; a second connecting point connected to the center of an edge of the second line included in the second resonator out of the resonators; and a third line formed between the first connecting point and the second connecting point as a microstripline. Furthermore, a length of the third line is desirably equal to or shorter than 80 μm when a width of the third line and widths of the second lines included in both the first and second resonators are respectively 200 μm. The reason will be described hereinafter.

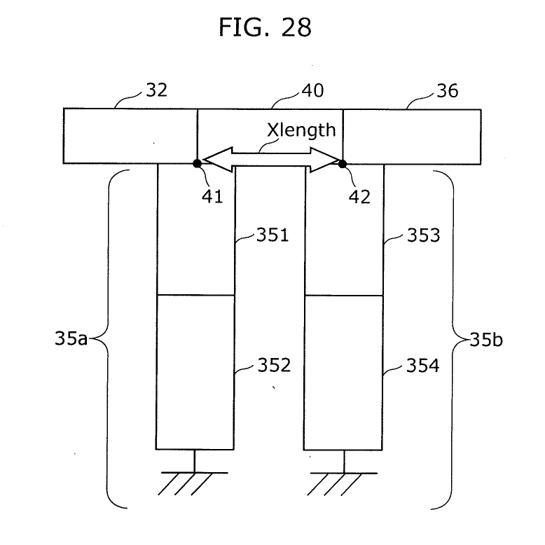

FIG. 28 schematically illustrates a resonance circuit including a microstripline between the resonators 35a and 35b. A microstripline 40 is connected to the resonator 35a at a connecting point 41, and to the resonator 35b at a connecting point 42. A X-length showing a length of the microstripline 40 is a distance between the connecting points 41 and 42.

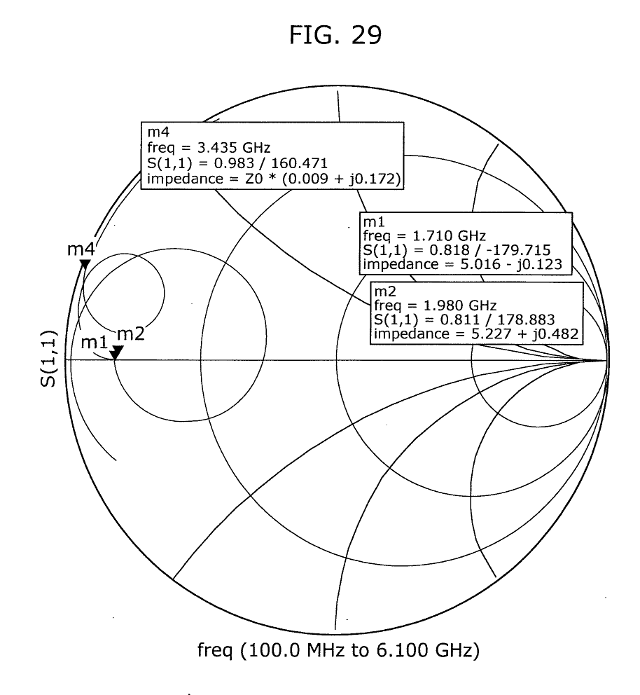

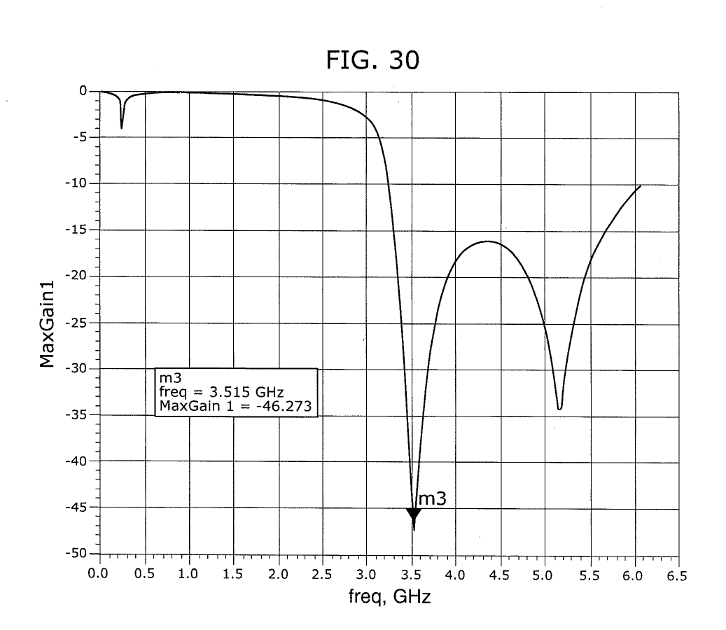

FIG. 29 shows a Smith chart representing impedances of an output matching circuit when the X-length is 0.8 mm. FIG. 30 shows a graph indicating a passing characteristic under such a condition.

FIG. 29 shows that the impedances are matched to 50 ohm in a bandwidth of the fundamental even when the X-length is 0.8 mm. FIG. 30 shows that the second harmonic can be suppressed.

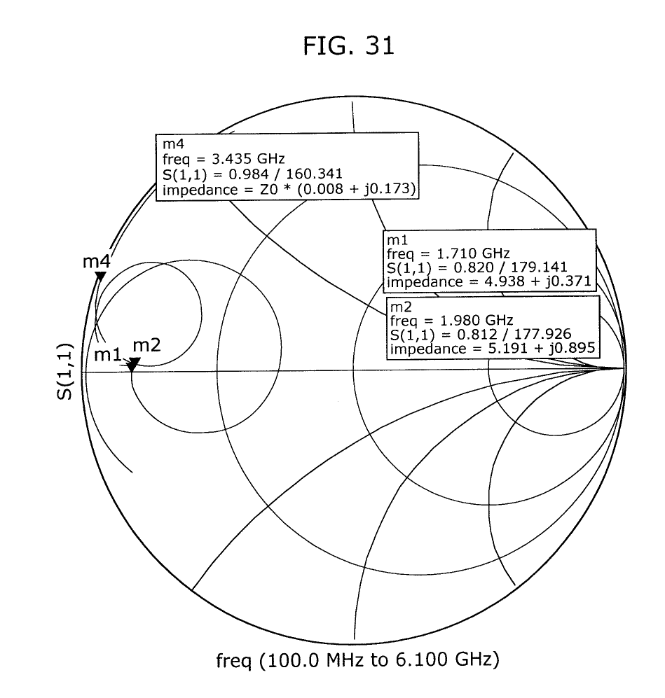

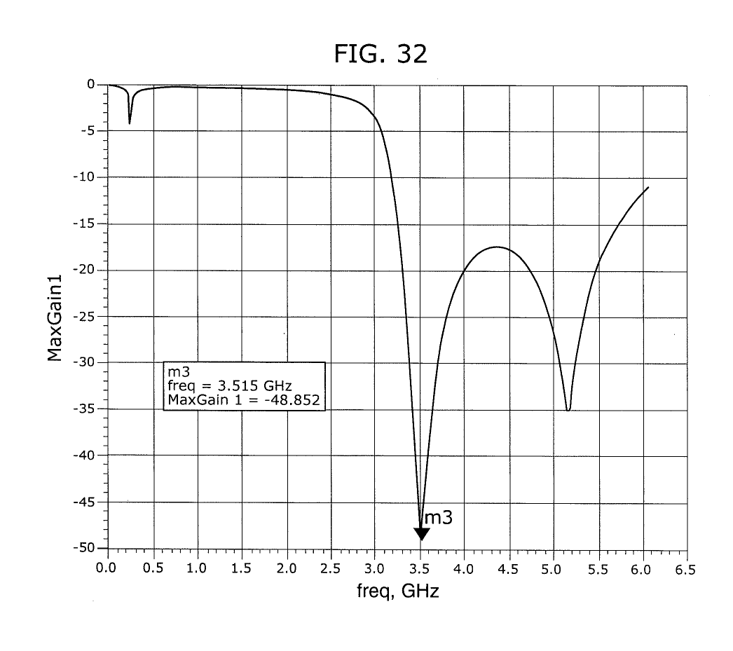

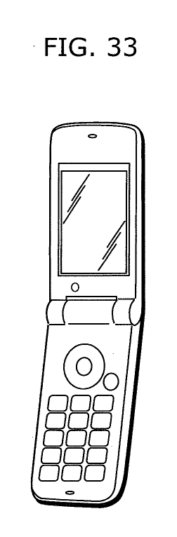

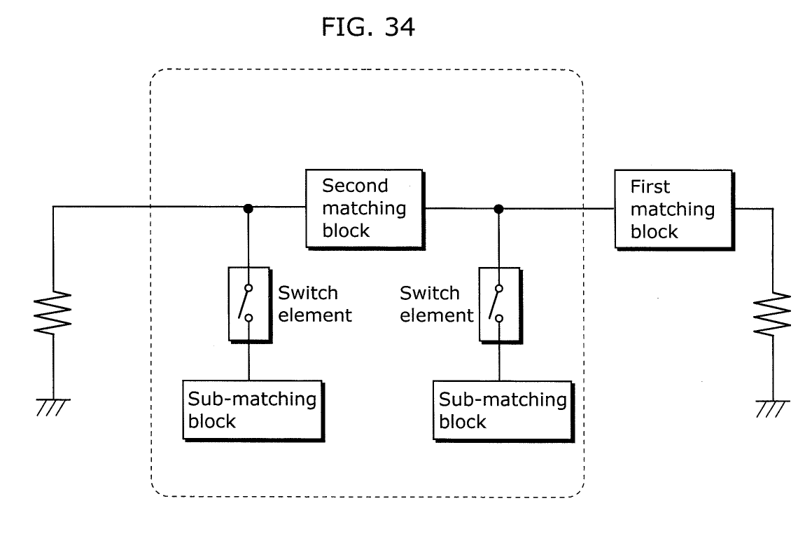

Next, a case where the X-length is 1.0 mm will be described. FIG. 31 shows a Smith chart representing impedances of an output matching circuit when the X-length is 1.0 mm. FIG. 32 shows a graph indicating a passing characteristic under such a condition.

FIGS. 31 and 32 show that the second harmonic can be suppressed in a bandwidth twice a bandwidth of the fundamental while the output matching circuit matches impedances even when the X-length is 1.0 mm.

However, when the X-length is 1.0 mm, a length of the microstripline 351 in the resonator 35a and a length of the microstripline 353 in the resonator 35b become 0.19 mm. Actually, the capacitors 352 and 354 for use in mounting a matching circuit of the present invention on a substrate have a chip size of 0.6 mm×0.3 mm. Thus, the capacitors 352 and 354 cannot be connected to the microstriplines 351 and 353 having the length of 0.19 mm.

Thus, the X-length is desired to be equal to or smaller than 0.8 mm.

Furthermore, the output matching circuit according to the present invention may be used in an RF power amplifier and a mobile phone including such an RF power amplifier as illustrated in FIG. 33. Furthermore, the output matching circuit may be used in a wireless transmitter and a circuit for transmitting a radio-frequency signal.

Although Embodiments 1 to 3 are described for an output matching circuit, these may be applied to an input matching circuit.

### INDUSTRIAL APPLICABILITY

The matching circuit, RF power amplifier, and mobile phone according to the present invention are applicable to an circuit for matching impedances, and a wireless transmitter and a circuit for transmitting a radio-frequency signal.

What is claimed is:

1. A matching circuit, comprising:
a transmission line through which a radio-frequency signal is transmitted; and
resonators each of which includes a capacitor, said resonators respectively having (i) first terminals connected to substantially a same connecting point on said transmission line and (ii) second terminals that are grounded.

2. The matching circuit according to claim 1,
wherein each of said resonators has a resonant frequency within a bandwidth twice a bandwidth of the radio-frequency signal transmitted through said matching circuit.

3. The matching circuit according to claim 2,
wherein one of said resonators has a resonant frequency different from at least one of the other resonant frequencies of a corresponding one of said resonators.

4. The matching circuit according to claim 1,
wherein said transmission line includes a first line formed as a microstripline, and
each of said resonators further includes a second line that is formed as a microstripline and that is connected in series with a corresponding one of said capacitors.

5. The matching circuit according to claim 4,
wherein first terminals of said second lines are connected to the connecting point, and first terminals of said capacitors are grounded.

6. The matching circuit according to claim 1,
wherein said transmission line includes a first line formed as a microstripline, and
each of said resonators further includes an inductor connected in series with a corresponding one of said capacitors.

7. The matching circuit according to claim 4,
wherein one of said capacitors included in a corresponding one of said resonators has a capacitance different from at least one of other capacitances of the other one of said capacitors of said resonators.

8. The matching circuit according to claim 4,
wherein said first line is formed on a substrate, and
said resonators are arranged in one of areas divided by said first line formed on the substrate.

9. The matching circuit according to claim 8,
wherein said first line is right-angled at the connecting point,
each of said resonators is linearly arranged,
a longitudinal direction of one of said resonators is vertical to a longitudinal direction of at least the other one of said resonators, and
the longitudinal directions of said resonators are vertical to said first line.

10. The matching circuit according to claim 4,
wherein at least one of said resonators is connected to the connecting point through a via.

11. The matching circuit according to claim 10,
wherein said first line is formed on a substrate, and
one of said resonators is arranged to be symmetric to the other one of said resonators with respect to said first line.

12. A radio-frequency power amplifier that amplifies a signal, said radio-frequency power amplifier comprising:
a transistor; and
a matching circuit including (i) a transmission line connected to an output terminal of said transistor and (ii) resonators,
wherein each of said resonators includes a capacitor, and has (i) first terminals connected to substantially a same connecting point on said transmission line and (ii) second terminals that are grounded.

13. The radio-frequency power amplifier according to claim 12,
wherein each of said resonators has a resonant frequency within a bandwidth twice a bandwidth of the radio-frequency signal transmitted through said matching circuit.

14. The radio-frequency power amplifier according to claim 12,
wherein said transmission line includes a first line formed as a microstripline, and
each of said resonators further includes a second line that is formed as a microstripline and that is connected in series with a corresponding one of said capacitors.

15. The radio-frequency power amplifier according to claim 14,
wherein one of said capacitors included in a corresponding one of said resonators has a capacitance different from at least one of other capacitances of the other one of said capacitors of said resonators.

16. The radio-frequency power amplifier according to claim 14,
wherein said first line is formed on a substrate, and
said resonators are arranged in one of areas divided by said first line formed on the substrate.

17. The radio-frequency power amplifier according to claim 16,
wherein said first line is right-angled at the connecting point,
each of said resonators is linearly arranged,
a longitudinal direction of one of said resonators is vertical to a longitudinal direction of at least the other one of said resonators, and
the longitudinal directions of said resonators are vertical to said first line.

18. The radio-frequency power amplifier according to claim 14,
wherein at least one of said resonators is connected to the connecting point through a via.

19. The radio-frequency power amplifier according to claim 18,
wherein said first line is formed on a substrate, and
one of said resonators is arranged to be symmetric to the other one of said resonators with respect to said first line.

20. A mobile phone, comprising
a radio-frequency power amplifier according to claim 12.
